(19) United States
(12) Patent Application Publication
(10) Pub. No.: US 2026/0349347 A1
(43) Pub. Date: Nov. 5, 2026

(54) METHOD OF FORMING SEMICONDUCTOR PATTERNS

(71) Applicant: Samsung SDI Co., Ltd., Yongin-si (KR)

(72) Inventors: Ran Namgung, Yongin-si (KR); Choong Bong LEE, Yongin-si (KR); Min Soo KIM, Yongin-si (KR)

(21) Appl. No.: 19/651,594

(22) Filed: Apr. 17, 2026

(30) Foreign Application Priority Data
Apr. 25, 2025 (KR) 10-2025-0054835

(51) Int. Cl. G03F 7/40; C07F 7/22; C08F 220/18; G03F 7/038; G03F 7/039; H10P 50/00; H10P 76/20

(52) U.S. Cl. CPC G03F 7/405; C07F 7/2224; C08F 220/1807; G03F 7/0388; G03F 7/039; H10P 76/2041; H10P 50/71; H10P 50/73

(57) ABSTRACT

A method of forming semiconductor patterns includes coating an organic photoresist composition on a substrate to form an organic photoresist layer; exposing and developing the organic photoresist layer to form an organic photoresist pattern on the substrate; overcoating a boron or metal-containing protective film composition on the substrate on which the organic photoresist pattern is formed; and developing the overcoated organic photoresist layer.

### CROSS-REFERENCE TO RELATED APPLICATION

The present application claims priority to and the benefit of Korean Patent Application No. 10-2025-0054835, filed on Apr. 25, 2025, in the Korean Intellectual Property Office, the entire content of which is incorporated herein by reference.

### BACKGROUND

### 1. Field

One or more embodiments of the present disclosure described herein relates to a method of forming semiconductor patterns.

### 2. Description of the Related Art

A photolithography process is performed by forming a resist film from a resist composition on a substrate, followed by selective exposure to light through a photomask having a set or predetermined pattern. Exposure may be carried out utilizing light, an electron beam, or other radiation sources to form a resist pattern with a corresponding shape in the resist film. The resist composition is referred to as a positive resist composition when the exposed region becomes soluble in a developer, and as a negative resist composition when the exposed region becomes insoluble in the developer.

With advances in photolithography technology, semiconductor devices and liquid crystal displays have undergone rapid miniaturization. One approach to achieving finer patterning involves shortening the wavelength of the exposure light. Historically, ultraviolet light sources such as g-lines and i-lines have been used. More recently, KrF excimer lasers (248 nm), ArF excimer lasers (193 nm), and F₂ excimer lasers (157 nm) have been adopted. In addition, the utilization of extreme ultraviolet (EUV) radiation, electron beams, and/or X-rays is under active investigation.

EUV lithography is a pattern-forming technology that utilizes EUV radiation with a wavelength of 13.5 nm as the exposure light source. This approach enables the formation of extremely fine patterns, such as those having dimensions of 20 nm or less, during semiconductor device fabrication. To achieve high-resolution patterning without collapse or degradation, thin film deposition may be required or desired. In addition, materials that enhance resistance during subsequent etching processes are desirable.

### SUMMARY

One or more aspects of embodiments of the present disclosure are directed toward a method for forming semiconductor patterns which prevents collapse of a miniaturized pattern and improves etch resistance of the pattern.

Additional aspects of embodiments will be set forth in part in the description which follows and, in part, will be apparent from the description, or may be learned by practice of the presented embodiments of the disclosure.

One or more embodiments of the present disclosure provides a method for forming semiconductor patterns that includes coating an organic photoresist composition on a substrate to form an organic photoresist layer; exposing and developing the organic photoresist layer to form an organic photoresist pattern on the substrate; overcoating a boron or metal-containing protective film composition on the substrate on which the organic photoresist pattern is formed; and developing the overcoated photoresist layer.

According to one or more embodiments of the present disclosure, a semiconductor pattern formed according to the method of forming semiconductor patterns is formed finely without collapsing and exhibits excellent or suitable etch resistance.

For example, one or more embodiments of present invention provide a method for forming a fine resist pattern utilizing a positive or negative photoresist composition, followed by the application and development of a protective film composition containing boron or metal-based compounds. The protective film enhances etch resistance and pattern fidelity during subsequent processing. The method enables the formation of extremely fine patterns suitable for EUV lithography and other advanced exposure techniques, and is compatible with various developer systems and solvent compositions disclosed herein.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1A to 1F are cross-sectional views for explaining a method of forming semiconductor patterns according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the teachings and scope of the present disclosure.

Hereinafter, referring to the drawings, embodiments are described in more detail. In the following description of the present disclosure, the well-suitable functions or constructions will not be described in order to clarify the present disclosure.

In order to clearly illustrate the present disclosure, the description and relationships are omitted, and throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto.

In the drawings, the thickness of layers, films, panels, regions, and/or the like, may be exaggerated or reduced for clarity, and like reference numerals designate like elements throughout the disclosure, and duplicative descriptions thereof may not be provided for conciseness. It will be understood that if (e.g., when) an element such as a layer, film, region, or substrate is referred to as being “on” another element, it may be directly on the other element or one or more intervening elements may also be present therebetween. In contrast, if (e.g., when) an element is referred to as being “directly on” another element, there are no intervening elements present.

As used herein, “substituted” may refer to replacement of a hydrogen atom of a compound by a substituent selected from among deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” may refer to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” may refer to a monovalent cyclic aliphatic saturated hydrocarbon group.

The cycloalkyl group may be a C3 to C8 cycloalkyl group, for example, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

As used herein, “aryl group” may refer to a substituent in which all atoms in the cyclic substituent have a p-orbital and these p-orbitals are conjugated and may include a monocyclic or fused ring polycyclic functional group (i.e., rings sharing adjacent pairs of carbon atoms) functional group.

As used herein, “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. When the heteroaryl group is a fused ring, one or more rings thereof may include one to three heteroatoms.

As used herein, unless otherwise defined, “alkenyl group” may refer to an aliphatic unsaturated alkenyl group including at least one double bond as a linear or branched aliphatic hydrocarbon group.

As used herein, unless otherwise defined, “alkynyl group” may refer to an aliphatic unsaturated alkynyl group including at least one triple bond as a linear or branched aliphatic hydrocarbon group.

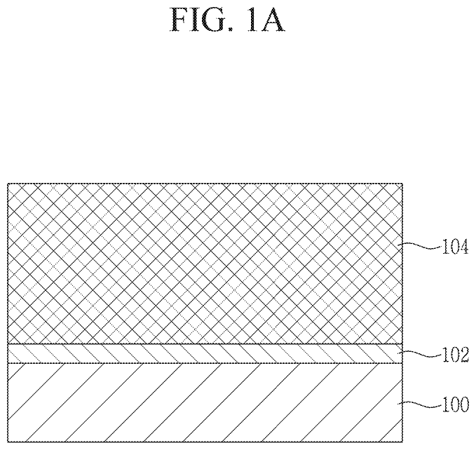

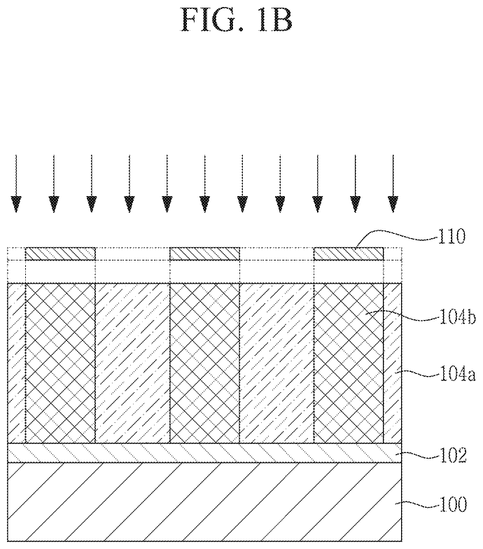

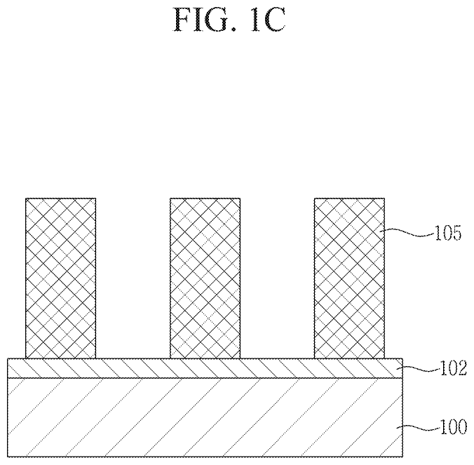

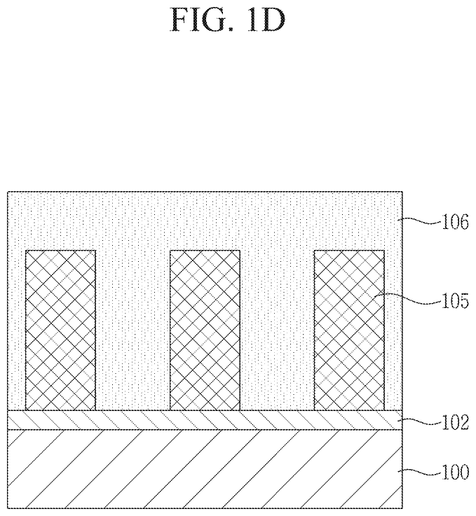

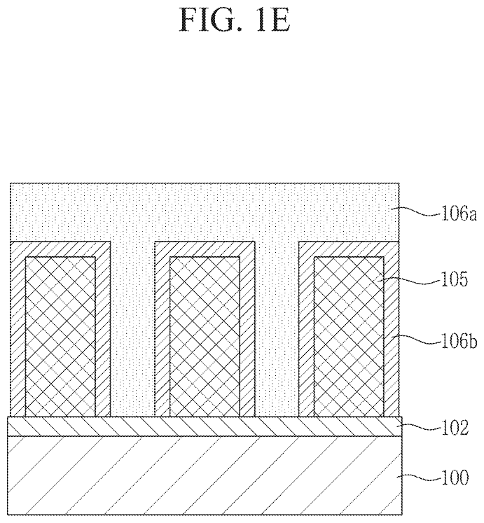

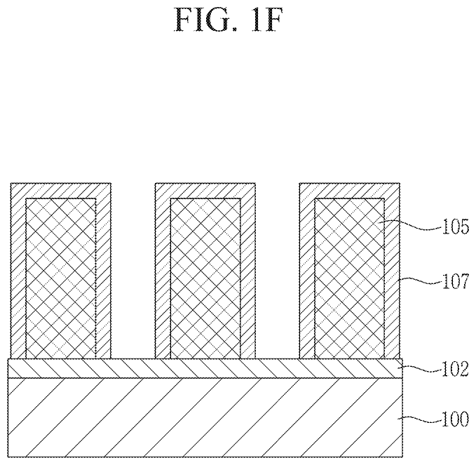

Hereinafter, a method of forming semiconductor patterns according to one or more embodiments is described referring to FIGS. 1A to 1F.

A method of forming semiconductor patterns according to one or more embodiments includes coating an organic photoresist composition on a substrate to form an organic photoresist layer; exposing and developing the organic photoresist layer to form an organic photoresist pattern on the substrate; overcoating a boron or metal-containing protective film composition on the substrate on which the organic photoresist pattern is formed; and developing the overcoated photoresist layer.

FIGS. 1A to 1F are a cross-sectional view for explaining a method of forming semiconductor patterns according to one or more embodiments.

Referring to FIG. 1A, an aspect for etching is prepared. The object for etching may be a thin film 102 formed on a semiconductor substrate 100, for example through a deposition process, such as using a vacuum deposition apparatus.

Hereinafter, the aspect for etching is limited to the thin film 102. A surface of the thin film 102 is washed to remove impurities and/or the like remaining thereon. In one or more embodiments, the thin film 102 may be, for example, a silicon nitride layer, a polysilicon layer, or a silicon oxide layer.

Subsequently, the resist underlayer composition for forming a resist underlayer is spin-coated on the surface of the washed thin film 102. However, the embodiments are not limited thereto, and suitable one or more suitable coating methods, for example a spray coating, a dip coating, a knife edge coating, a printing method, for example an inkjet printing and a screen printing, and/or the like may be used.

Then, the coated resist underlayer composition is dried and baked to form a resist underlayer on the thin film 102. The baking may be performed at about 100 °C to about 500 °C, for example, about 100 °C to about 300 °C. The resist underlayer is formed between the substrate and the photoresist film, and may prevent or reduce the photoresist linewidth from becoming uneven and the pattern forming property from being disturbed if (e.g., when) the radiation reflected from the interface between the substrate and the photoresist film or the interlayer hardmask is scattered into an unintended photoresist region.

The process of forming a resist underlayer on the surface of the thin film has been described above and may not be repeated for conciseness.

The forming of the organic photoresist layer on the substrate may include a process of coating an organic photoresist composition on a thin film 102 or a resist underlayer by spin coating, slit coating, inkjet printing, and/or the like, and drying it to form an organic photoresist film 104. The organic photoresist film 104 may be in the form that the organic photoresist composition is coated on a thin film 102 formed on a substrate 100 and then cured through heat treatment.

Subsequently, a substrate 100 having the photoresist film 104 is subjected to a first baking process. The first baking process may be performed at about 80 °C to about 120 °C.

Referring to FIG. 1B, the organic photoresist film 104 formed above is selectively exposed using a patterned mask 110. The exposed region 104a and the unexposed region 104b of the organic photoresist film 104 have different solubilities in the developer.

Subsequently, the substrate 100 on which the organic photoresist film 104 is formed is subjected to a second baking process. In one or more embodiments, the second baking process may be performed at a temperature of about 90 °C to about 200 °C. By performing the second baking process, the unexposed region of the organic photoresist film 104 becomes indissoluble in the developer.

Subsequently, as shown in FIG. 1C, the organic photoresist pattern 105 is formed by dissolving and removing the exposed organic photoresist film 104 corresponding to the exposed region 104a using a developer.

For example, the exposure may use an activation radiation with light having a high energy wavelength, such as EUV (extreme ultraviolet; a wavelength of about 13.5 nm), an E-Beam (an electron beam), and/or the like as well as light such as an i-line (a wavelength of about 365 nm), a KrF excimer laser (a wavelength of about 248 nm), an ArF excimer laser (a wavelength of about 193 nm), and/or the like. More specifically, light for the exposure according to one or more embodiments may be light in a range of about 5 nm to about 150 nm and a high energy wavelength, for example, EUV (extreme ultraviolet; a wavelength of 13.5 nm), an E-Beam (an electron beam), and/or the like.

In one or more embodiments, the organic photoresist pattern 105 formed by the exposure to light having a high energy wavelength and/or the like may have a width of about 5 nm to about 100 nm, for example, about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm. In contrast, the photoresist pattern 105 may have line width roughness having a half-pitch of less than or equal to about 50 nm, for example, less than or equal to about 40 nm, for example, less than or equal to about 30 nm, for example, less than or equal to about 20 nm, or for example, less than or equal to about 15 nm and a pitch of less than or equal to about 10 nm, less than or equal to about 5 nm, less than or equal to about 3 nm, or less than or equal to about 2 nm.

Subsequently, on the substrate on which the organic photoresist pattern 105 is formed, as shown in FIG. 1D, a boron or metal-containing protective film composition is overcoated. The overcoated boron or metal-containing protective film composition may have a ligand exchange reaction with the organic photoresist pattern 105. In one or more embodiments, the boron or metal-containing protective film composition may form an ether bond (—O—) or ester bond (—C(═O)O—) with the organic photoresist pattern. For example, the boron or metal-containing protective film composition may be overcoated on the organic photoresist pattern 105 and have the ligand exchange reaction with the surface of the organic photoresist pattern 105 to form the ether bond or ester bond.

For example, boron or metal included in the boron or metal-containing protective film composition to be described later may be bonded to an oxygen atom of the organic photoresist pattern 105, if (e.g., when) the boron or metal-containing protective film composition may be overcoated on the surface of the organic photoresist pattern 105.

Herein, a third baking process of heating the substrate 100 having the organic photoresist pattern 105 overcoated with the boron or metal-containing protective film composition may be performed at about 90 °C to about 200 °C. The third baking process may increase the reactivity with the boron or metal-containing protective film composition on the surface of the organic photoresist pattern 105.

Referring to FIG. 1E, the boron or metal-containing protective film composition overcoated on the organic photoresist pattern 105 may be divided to an unreacted region 106a not reacting with the organic photoresist pattern and a reacted region 106b reacting with the organic photoresist pattern. Herein, the unreacted region 106a and the reacted region 106b have different solubility for specific solvents.

Subsequently, the organic photoresist layer overcoated with the boron or metal-containing protective film composition is developed. The development of the organic photoresist layer overcoated with the boron or metal-containing protective film composition, as shown in FIG. 1F, includes a process of removing the unreacted region 106a where the boron or metal-containing protective film composition does not react with the organic photoresist pattern with a solution to form a protective layer pattern 107 derived from the reacted region 106b reacting with the organic photoresist pattern.

The composition used in the aforementioned method of forming semiconductor patterns is described in more detail.

In the coating of the organic photoresist composition on the substrate to form the organic photoresist layer of the method of forming semiconductor patterns according to some example embodiments, the organic photoresist composition may undergo a ligand exchange reaction with the boron or metal-containing protective film composition, or may form an ether bond or ester bond with the boron or metal-containing protective film composition.

In one or more embodiments, the organic photoresist composition may include a polymer including one or more of the structural units represented by Chemical Formula 1 to Chemical Formula 4:

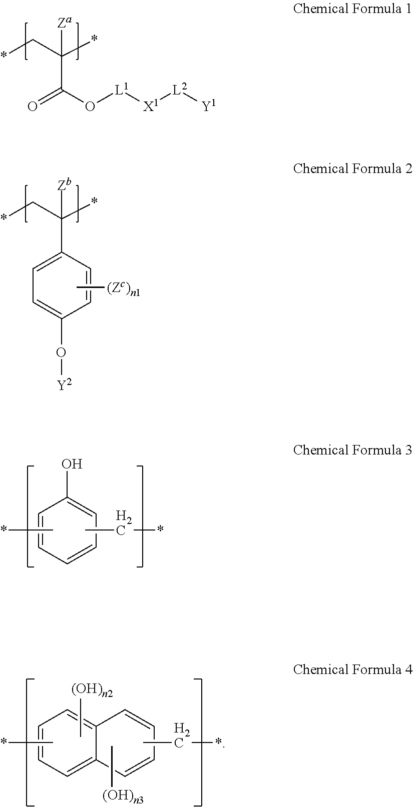

In Chemical Formula 1 and Chemical Formula 2,
L¹ and L² may each independently be a single bond, adamantanediol, a substituted or unsubstituted C1 to C10 alkylene group, a substituted or unsubstituted C3 to C10 cycloalkylene group, a substituted or unsubstituted C1 to C20 arylene group, or a combination thereof,
X¹ is a single bond, —O—, —S—, —S(═O)—, —S(═O)₂—, —C(═O)—, —(C═O)O—, —O(C═O)O—, —NR^{a}— (wherein, R^{a} is hydrogen, deuterium, or a C1 to C10 alkyl group), or a combination thereof,
Y¹ and Y² may each independently be hydrogen, a hydroxyl group, an adamantyl group, a substituted or unsubstituted C1 to C10 alkyl group, a substituted or unsubstituted C2 to C10 alkenyl group, a substituted or unsubstituted C3 to C20 cycloalkyl group, a substituted or unsubstituted C2 to C20 cycloalkenyl group, a substituted or unsubstituted C6 to C20 aryl group, or a combination thereof,
Z^{a} and Z^{b} may each independently be hydrogen or a methyl group,
Z^{c} is a hydroxyl group, a substituted or unsubstituted C1 to C5 alkoxy group, a substituted or unsubstituted C1 to C5 alkyl group, or a combination thereof, and
n1 is one of the integers 0 to 4.

In Chemical Formula 4,
n2 and n3 may each independently be an integer from 0 to 3, and n2+n3 is greater than or equal to 1.

The organic photoresist composition may further include a photoacid generator other than the polymer. The photoacid generator is a compound that generates an acid if (e.g., when) irradiated with active light or radiation, and examples thereof may include a sulfonium salt compound, an iodonium salt compound, a diazonium salt compound, a phosphonium salt compound, an imidesulfonate compound, an oxime sulfonate compound, a diazodisulfone compound, a disulfone compound, and an o-nitrobenzylsulfonate compound.

Additionally, the organic photoresist composition may further include a solvent other than the polymer. The solvent may be an organic solvent, and for example, an organic solvent such as alkylene glycol monoalkyl ether carboxylate, alkylene glycol monoalkyl ether, alkyl lactate ester, alkyl alkoxypropionate, cyclic lactone (desirably having 4 to 10 carbon atoms), a monoketone compound that may have a ring (desirably having 4 to 10 carbon atoms), alkylene carbonate, alkyl alkoxyacetic acid, and alkyl pyruvate may be suitably used. For example, a mixed solvent including a solvent having a hydroxyl group in the structure and a solvent not having a hydroxyl group may be used.

As the solvent having the hydroxyl group and the solvent not having the hydroxyl group, the aforementioned example compounds may be appropriately or suitably selected, but the solvent having a hydroxyl group may be alkylene glycol monoalkyl ether, alkyl lactate, and/or the like, for example, propylene glycol monomethyl ether (PGME), propylene glycol monoethyl ether (PGEE), methyl 2-hydroxyisobutyrate, ethyl lactate, and/or the like. In one or more embodiments, the solvent not having the hydroxyl group may be alkylene glycol monoalkyl ether acetate, alkyl alkoxy propionate, monoketone compound which may have a ring, cyclic lactone, or alkyl acetate, for example, propylene glycol monomethyl ether acetate (PGMEA), ethyl ethoxypropionate (specifically, ethyl 3-ethoxypropionate), 2-heptanone, γ-butyrolactone, cyclohexanone, cyclopentanone, 3-methoxybutyl acetate, or butyl acetate, and for example, propylene glycol monomethyl ether acetate, γ-butyrolactone, ethyl ethoxypropionate, cyclohexanone, cyclopentanone, or 2-heptanone. The solvent not having the hydroxyl group may include propylene carbonate.

In the overcoating of the boron or metal-containing protective film composition on a substrate on which an organic photoresist pattern is formed of the method for forming the semiconductor pattern according to one or more embodiments, the boron or metal-containing protective film composition may perform a ligand exchange reaction with the organic photoresist pattern. Additionally, the boron or metal-containing protective film composition may form an ether bond or ester bond with the organic photoresist pattern. The boron or metal-containing protective film composition may be overcoated on the surface of an organic photoresist pattern by forming an ether bond or an ester bond through a ligand exchange reaction with the organic photoresist pattern.

The boron or metal-containing protective film composition may include at least one selected from among boron (B), aluminum (AI), titanium (Ti), zirconium (Zr), hafnium (Hf), tin (Sn), antimony (Sb), and tellurium (Te), and may include, for example, boron (B) or tin (Sn). Because the protective film composition for overcoating an organic photoresist pattern includes a compound containing boron or the metal, the protective film composition may undergo a ligand exchange reaction with the organic photoresist pattern and may be overcoated on the photoresist pattern without adding a separate process.

In one or more embodiments, the boron or metal-containing protective film composition includes a compound represented by Chemical Formula 5:

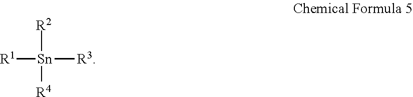

In Chemical Formula 5,
R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido or dialkylamido (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and

at least one of R² to R⁴ is selected from among alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido or dialkylamido (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

At least one of R² to R⁴ may be selected from among alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In one or more embodiments, the compound represented by Chemical Formula 5 may further increase a reactivity of the ligand exchange reaction with the organic photoresist pattern of the metal-containing protective film composition by including —OR^{b} or —OC(═O)R^{c} as a ligand. In addition, the ligand of —OR^{b} or —OC(═O)R^{c} may determine the solubility of the compound represented by Chemical Formula 5 in a solvent, thereby controlling overcoating properties of the metal-containing protective film composition including it.

R¹ may be selected from among a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and a substituted or unsubstituted C7 to C20 arylalkyl group,

R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and

R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof,

R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and

R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

Additionally, the boron or metal-containing protective film composition may include at least one of a compound represented by Chemical Formula 6 and a compound represented by Chemical Formula 7:

R⁵_{z}SnO_{(2-(z/2)-(x/2))}(OH)ₓ. Chemical Formula 6

In Chemical Formula 6, R⁵ is a C1 to C31 hydrocarbyl group, 0<z≤2, and 0<(z+x)≤4;

R⁶ₐSn_{b}X_{c}Y_{d}, Chemical Formula 7
wherein, in Chemical Formula 7, R⁶ is a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te),
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d may each independently be an integer of 1 to 20.

In one or more embodiments, the boron or metal-containing protective film composition may include a compound represented by Chemical Formula 8 or Chemical Formula 9, or a polymer thereof:

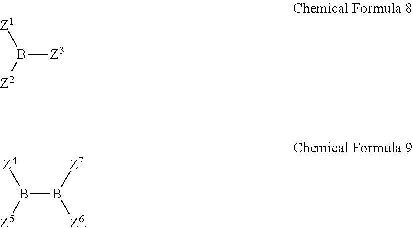

In Chemical Formula 8 and Chemical Formula 9,
Z¹ to Z⁷ may each independently be hydrogen, deuterium, a hydroxyl group, a halogen, a nitro group, a cyano group, —NY^{a}Y^{b} (wherein, Y^{a} and Y^{b} may each independently be hydrogen, deuterium, a substituted or unsubstituted C1 to C10 alkyl group, a substituted or unsubstituted C6 to C20 aryl group, or a combination thereof), —OY^{c} (wherein, Y^{c} is a halogen, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C6 to C20 aryl group, or a combination thereof), a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C3 to C20 heterocycloalkyl group, a substituted or unsubstituted C6 to C20 aryl group, a substituted or unsubstituted C3 to C20 heteroaryl group, or a combination thereof, provided that two of Z¹ to Z³ groups and two of Z⁴ to Z⁷ groups are optionally linked to each other to form a ring.

Z¹ to Z⁷ may each independently be hydrogen, deuterium, a hydroxyl group, a halogen, a nitro group, a cyano group, —NH₂, —NHCH₃, —N(CH₃)₂, —OY^{c} (wherein, Y^{c} is a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof), a substituted or unsubstituted C1 to C20 alkyl group, a substituted or unsubstituted C2 to C20 alkenyl group, a substituted or unsubstituted C3 to C20 cycloalkyl group, a substituted or unsubstituted C3 to C20 heterocycloalkyl group, a substituted or unsubstituted C6 to C20 aryl group, a substituted or unsubstituted C3 to C20 heteroaryl group, or a combination thereof, and may be, for example, hydrogen, a hydroxyl group, a halogen, —OY^{c} (wherein, Y^{c} is a substituted or unsubstituted C1 to C20 alkyl group, a substituted or unsubstituted C2 to C20 alkenyl group, or a combination thereof), a substituted or unsubstituted C1 to C20 alkyl group, a substituted or unsubstituted C2 to C20 alkenyl group, a substituted or unsubstituted C6 to C20 aryl group, or a combination thereof.

Two groups among Z¹ to Z³ of Chemical Formula 8 may be optionally linked to each other to form a ring, that is, Z¹ to Z³ may each be an independent group, or two selected groups among Z¹ to Z³ may be linked to each other to form a ring.

Two groups among Z⁴ to Z⁷ of Chemical Formula 9 may be optionally linked to each other to form a ring, that is, Z⁴ to Z⁷ may each be an independent group, or two groups selected from among Z⁴ to Z⁷ may be linked to each other to form a ring.

In one or more embodiments, the boron or metal-containing protective film composition may include Al(OR^{p})₃, Ti(OR^{q})₄, Zr(OR^{r})₄, Hf(OR^{s})₄, Sb(OR^{t})₃, Te(OR^{u})₄, TeR^{v}₄, or a combination thereof, wherein RP to Ru may each independently be, —C(═O)R^{x} (wherein, R^{x} is a substituted or unsubstituted C1 to C10 alkyl group), a substituted or unsubstituted C1 to C10 alkyl group, or a substituted or unsubstituted C6 to C20 aryl group, or a combination thereof, and R^{v} is a halogen.

As an example, the boron or metal-containing protective film composition may include a compound represented by one or more selected from among Chemical Formula 11 to Chemical Formula 26:

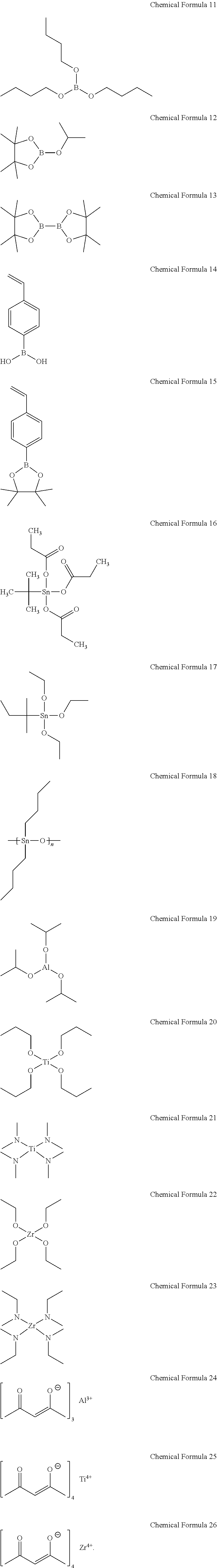

The boron or metal-containing protective film composition may further include a solvent in addition to the above-mentioned compound. The solvent may be an organic solvent, and may be for example aromatic compounds (e.g., xylene, toluene, and/or the like), an alcohol (e.g., 4-methyl-2-pentanol, 4-methyl-2-propanol, 1-butanol, methanol, isopropyl alcohol, 1-propanol), an ether (e.g., anisole, tetrahydrofuran), an ester (n-butyl acetate, propylene glycol monomethyl ether acetate, ethyl acetate, ethyl lactate), a ketone (e.g., methyl ethyl ketone, 2-heptanone), or a mixture thereof, but the present disclosure is not limited thereto.

The boron or metal-containing protective film composition may include a compound represented by Chemical Formula 5 to Chemical Formula 26, Al(OR^{p})₃, Ti(OR^{q})₄, Zr(OR^{r})₄, Hf(OR^{s})₄, Sb(OR^{t})₃, Te(OR^{u})₄, or TeR^{v}₄ in an amount of about 0.1 wt % to about 30 wt %, for example about 1 wt % to about 30 wt %, about 1 wt % to about 25 wt %, about 1 wt % to about 20 wt %, about 1 wt % to about 15 wt %, about 1 wt % to about 10 wt %, about 1 wt % to about 5 wt %, based on the total weight of 100% the boron or metal-containing protective film composition. By including the aforementioned compound in the boron or metal-containing protective film composition in the above amount range, the ligand exchange reactivity with the organic photoresist pattern may be further increased.

In addition to the aforementioned compound, the boron or metal-containing protective film composition may further include additives.

Examples of the additives may be a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but the present disclosure is not limited thereto.

The crosslinking agent may be for example a melamine-based crosslinking agent, a substituted urea-based crosslinking agent, an acryl-based crosslinking agent, an epoxy-based crosslinking agent, or a polymer-based crosslinking agent, but the present disclosure is not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but the present disclosure is not limited thereto.

The quencher may be diphenyl (p-tolyl) amine, methyl diphenyl amine, triphenyl amine, phenylenediamine, naphthylamine, diaminonaphthalene, or a combination thereof.

Each use amount of the additives may be controlled or selected depending on desired or suitable properties.

In the forming an organic photoresist pattern on a substrate by exposing and developing the organic photoresist layer in the method of forming semiconductor patterns according to one or more embodiments, at least one selected from among tetramethylammonium hydroxide, tetraethylammonium hydroxide, tetrapropylammonium hydroxide, tetrabutylammonium hydroxide, and normal butyl acrylate (e.g., n-butyl acetate) may be used as a developer for developing the organic photoresist layer.

In the developing the overcoated organic photoresist layer in the method of forming semiconductor patterns according to one or more embodiments, any solution that can remove the boron or metal-containing protective film composition that has not reacted with the organic photoresist pattern may be used as the developer for the overcoated organic photoresist layer, and for example, at least one selected from among methyl ethyl ketone, acetone, cyclohexanone, 2-heptanone, 4-methyl-2-propanol, 1-butanol, isopropanol, 1-propanol, methanol, propylene glycol monomethyl ether acetate, ethyl acetate, ethyl lactate, n-butyl acetate, butyrolactone, dibutyl ether, diisopentyl ether, propylene glycol monomethyl ether, benzene, xylene, and toluene may be used.

Hereinafter, the present disclosure will be described in more detail through examples of the preparation of the aforementioned semiconductor photoresist composition. However, the present disclosure is technically not restricted by the following examples.

### Synthesis of Boron or Metal-Containing Protective Film Compositions

### Synthesis Example 1

In a 250 mL 2-neck round-bottomed flask, 40.7 g of t-butylSnPh₃ and 300 g of propionic acid were added and then, heated under reflux for 24 hours. Under a reduced pressure, the unreacted propionic acid was removed, obtaining a compound represented by Chemical Formula 16. Herein, the obtained compound was dissolved at a concentration of 3 wt % in propylene glycol methyl ether acetate (PGMEA), obtaining a metal-containing protective film composition.

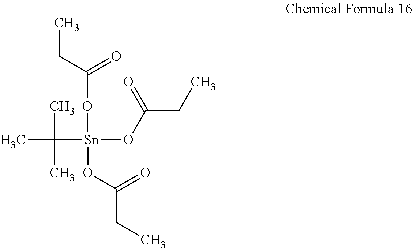 [SMILES: CCC(=O)[O][Sn]([O]C(=O)CC)([O]C(=O)CC)[C](C)(C)C]

### Synthesis Example 2

30 mL of anhydrous pentane was added to 10 g of t-AmylSnCl₃, and while maintaining at 0 °C, 7.4 g of diethyl amine and 6.1 g of ethanol were added thereto and then, stirred at room temperature for 1 hour. When a reaction was completed, the resultant was filtered, concentrated, and vacuum-dried, obtaining a compound represented by Chemical Formula 17. Herein, the obtained compound was dissolved at a concentration of 3 wt % in propylene glycol methyl ether acetate (PGMEA), obtaining a metal-containing protective film composition.

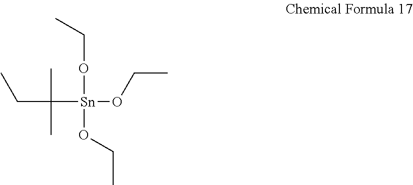

### Synthesis Example 3

10 g of dibutyltin dichloride was dissolved in 30 ml of ether, and 70 mL of a 1 M sodium hydroxide (NaOH) aqueous solution was added thereto and then stirred for 1 hour. After the stirring, a solid produced therein was filtered, 3 times washed with 25 mL of deionized water, and dried at 100 °C under a reduced pressure, obtaining an organometallic compound represented by Chemical Formula 18 and having an average molecular weight (Mw) of 1,500 g/mol. Herein, the obtained compound was dissolved at a concentration of 3 wt % in propylene glycol methyl ether acetate (PGMEA), obtaining a metal-containing protective film composition.

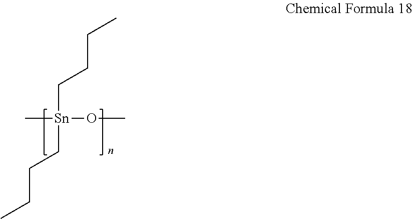

### Synthesis Example 4

A compound represented by Chemical Formula 15 (Sigma-Aldrich Corporation) was dissolved at a concentration of 3 wt % in propylene glycol methyl ether acetate (PGMEA), obtaining a metal-containing protective film composition.

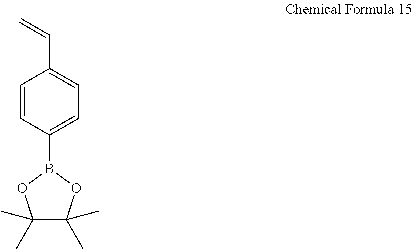

### Synthesis of Organic Photoresist Compositions

### Synthesis Example 5

After attaching a condenser, a stirrer, and a thermometer to a 5 L round-bottomed flask, the flask was dipped in an oil bath. To the corresponding flask, 134 g of 1-methylcyclohexyl methacrylate (ALFA Chemistry), 64 g of 4-acetoxystyrene (Songwon), 20 g of azobisisobutynitrile, and 550 g of 1,4-dioxane were added, stirred, and then heated to 90 °C and stirred for 5 hours. After lowering the internal temperature of the reactor to room temperature (25±2 °C), 1,500 g of n-heptane was added thereto and then stirred for 30 minutes and allowed to stand for 1 hour, and then, a supernatant was removed therefrom. Subsequently, the residual solvent was removed through vacuum distillation, obtaining 95 g of an intermediate (average molecular weight (Mw=5,500 g/mol, PDI=1.33, MCH/AS=0.62/0.38).

After attaching a condenser, a stirrer, and a thermometer to a 5 L round-bottomed flask, the flask was dipped in an oil bath. To this flask, 80 g of the above intermediate, 20 g of hydrazine monohydrate, 160 g of 1,4-dioxane, and 240 g of methanol were added and then, stirred, while heating to 70 °C. After 6 hours, the internal temperature of the reactor was lowered to room temperature, and the reaction solution was concentrated to a total mass of 160 g. Subsequently, 320 g of ethyl acetate and 320 g of a 10% acetic acid aqueous solution were added thereto and then, stirred for 30 minutes, moved to a separatory funnel, and allowed to stand for 1 hour to remove a lower water layer. The remaining organic layer was washed with 320 g of DIW. After adding 300 g of PGME to the washed polymer solution, the residual organic solvent and moisture were removed through vacuum distillation, finally obtaining a polymer (Mw=5,400 g/mol, PDI=1.32) solution for an organic photoresist composition.

3 g of the prepared polymer, 0.75 g of triphenylsulfonium nonafluorobutanesulfonate (T3038, TCI), and 0.45 g of triethanolamine (S0377, TCI) were dissolved in a mixed solvent of 148 g of PGMEA and 98 g of PGME and then, stirred at room temperature for 24 hours and filtered with TEFLON (tetrafluoroethylene) filter having a pore size of 0.45 μm, obtaining an organic photoresist composition.

### Formation of Patterns

### Example 1

The organic photoresist composition of Synthesis Example 5 was spin-coated on a 200 mm circular silicon wafer at 1500 rpm for 30 seconds, post-apply baked (PAB) at 130 °C for 60 seconds to form an organic photoresist layer.

Subsequently, a linear array with a line width of 180 nm was exposed by using a KrF light source and projected onto the wafer on which the organic photoresist layer was formed. Next, the wafer was heated at 100 °C on a hot plate for 90 seconds. Then, the wafer was developed in a 2.38% tetraethylammonium hydroxide aqueous solution (TMAH) to form an organic photoresist pattern.

On the wafer on which the organic photoresist pattern was formed, the tin-containing protective layer composition of Synthesis Example 1 was overcoated by spin-coating at 1500 rpm for 30 seconds. Subsequently, the wafer on which the organic photoresist pattern was formed was heated at 90 °C for 45 seconds. After removing the unreacted tin-containing protective layer composition was removed with PGMEA, the wafer was heated at 100 °C on a hot plate for 50 seconds, forming a final pattern.

### Example 2

A final pattern of Example 2 was formed in substantially the same manner as in Example 1 except that the tin-containing protective layer composition of Synthesis Example 2 instead of the tin-containing protective layer composition of Synthesis Example 1 was overcoated on the wafer on which the organic photoresist pattern was formed.

### Example 3

A final pattern of Example 3 was formed in substantially the same manner as in Example 1 except that the tin-containing protective layer composition of Synthesis Example 3 instead of the tin-containing protective layer composition of Synthesis Example 1 was overcoated on the wafer on which the organic photoresist pattern was formed.

### Example 4

A final pattern of Example 4 was formed in substantially the same manner as in Example 1 except that the tin-containing protective layer composition of Synthesis Example 4 was overcoated on the wafer on which the organic photoresist pattern instead of the tin-containing protective layer composition of Synthesis Example 1 was formed.

### Comparative Example 1

The organic photoresist composition according to Synthesis Example 5 was spin-coated on a 200 mm circular silicon wafer at 1500 rpm for 30 seconds and post-apply baked (PAB) at 130 °C to form an organic photoresist layer.

Subsequently, a linear array with a line width of 180 nm was exposed by using a KrF light source and projected to the wafer on which the organic photoresist layer was formed. Next, the wafer was heated at 100 °C on a hot plate for 90 seconds. Then, the wafer was developed in a 2.38% tetraethylammonium hydroxide aqueous solution (TMAH) to form an organic photoresist pattern.

### Evaluation: Evaluation of Etch Resistance

Each of the photoresist patterns of Examples 1 to 4 and Comparative Example 1 was etched with CF₄ gas or O₂ gas for 20 seconds to measure a thickness before and after the etching, which was used to calculate an etch-rate. In addition, etch selectivity (i.e., an etch-rate of photoresist/etch-rate of substrate) of the photoresist pattern and the substrate was calculated. The thickness was measured by using ellipsometry. Referring to Table 1, when the etch-rate and etch selectivity of Comparative Example 1 was set to 1, each etch-rate and etch selectivity of the other examples was calculated as a relative value.

TABLE 1

| | CF₄ gas | O₂ gas | Selectivity |
|---|---|---|---|
| Example 1 | 0.56 | 0.03 | 1.8 |
| Example 2 | 0.52 | 0.04 | 1.9 |
| Example 3 | 0.47 | 0.03 | 2.1 |
| Example 4 | 0.65 | 0.07 | 1.7 |
| Comparative Example 1 | 1.00 | 1.00 | 1.0 |

Referring to Table 1, the photoresist patterns of the Examples exhibited a slower etch-rate for CF₄ gas and O₂ gas than that of Comparative Example 1 and also, larger selectivity than that of Comparative Example 1. For example, the photoresist patterns of the examples were confirmed to exhibit excellent or suitable etch resistance and etch selectivity, compared to Comparative Example 1.

The above example results confirm that the protective film compositions described in Examples 1 through 4—each incorporating a distinct tin-containing compound synthesized according to Synthesis Examples 1 through 4—contribute to enhanced etch resistance and selectivity when applied over the organic photoresist pattern. The ligand exchange reactions and formation of ether or ester bonds between the protective film and the photoresist pattern, as described above, are believed to improve structural integrity during plasma etching. Accordingly, the disclosed method, including the sequence of resist coating, exposure, development, overcoating, and selective removal of unreacted protective film, as supported by the experimental data, enables the formation of fine semiconductor patterns with improved process reliability.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. In addition, the term “and/or” or “or” is not to be construed as an exclusive meaning, for example, “A and/or B” or “A or B” is construed to include A, B, A+B, and/or the like. The singular expression includes the plural expression unless the context clearly dictates otherwise. For example, the singular forms “a,” “an,” “one,” and “the” as used herein are intended to include the plural forms as well unless the context clearly indicates differently. Further, the utilization of “may” when describing embodiments of the present disclosure refers to “one or more embodiments of the present disclosure”.

It should be understood that terms such as “comprise(s)/comprising,” “include(s)/including,” and/or “has (have)/having” are intended to designate the presence of an embodied feature, number, step, element, or a combination thereof, but it does not preclude the possibility of the presence or addition of one or more other features, numbers, steps, elements, or a combination thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A pattern forming device, a semiconductor forming device and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, certain embodiments have been described and illustrated, however, it is apparent to a person with ordinary skill in the art that the present disclosure is not limited to the embodiments as described, and may be variously modified and transformed without departing from the teachings and scope of the present disclosure. Accordingly, the modified or transformed embodiments as such may not be understood separately from the technical ideas and aspects of the present disclosure, and the modified embodiments are within the scope of the claims of the present disclosure. It is further to be understood that the scope of the present disclosure is defined by the appended claims and equivalents thereof rather than the detailed description described above, and all modifications and alterations derived from the claims and their equivalents fall within the scope of the present disclosure.

Reference Numerals

| | |
|---|---|
| 100: | substrate |
| 102: | thin film |
| 104: | organic photoresist film |
| 104a: | exposed region |
| 104b: | unexposed region |
| 105: | organic photoresist pattern |
| 106: | protective layer |
| 106a: | unreacted region |
| 106b: | reacted region |
| 107: | protective layer pattern |
| 110: | mask |

What is claimed is:

1. A method comprising:
coating an organic photoresist composition on a substrate to form an organic photoresist layer;
exposing and developing the organic photoresist layer to form an organic photoresist pattern on the substrate;
overcoating a boron or metal-containing protective film composition on the substrate on which the organic photoresist pattern is formed to form an overcoated organic photoresist layer; and
developing the overcoated organic photoresist layer,
wherein the method is a method of forming semiconductor patterns.

2. The method as claimed in claim 1, wherein, during the overcoating of the boron or metal-containing protective film composition on the substrate on which the organic photoresist pattern is formed, the boron or metal-containing protective film composition perform a ligand exchange reaction with the organic photoresist pattern.

3. The method as claimed in claim 1, wherein, during the overcoating a boron or metal-containing protective film composition on the substrate on which the organic photoresist pattern is formed, the boron or metal-containing protective film composition forms an ether bond or an ester bond with the organic photoresist pattern.

4. The method as claimed in claim 1, wherein the organic photoresist composition comprises a polymer comprising one or more of the structural units represented by Chemical Formula 1 to Chemical Formula 4: 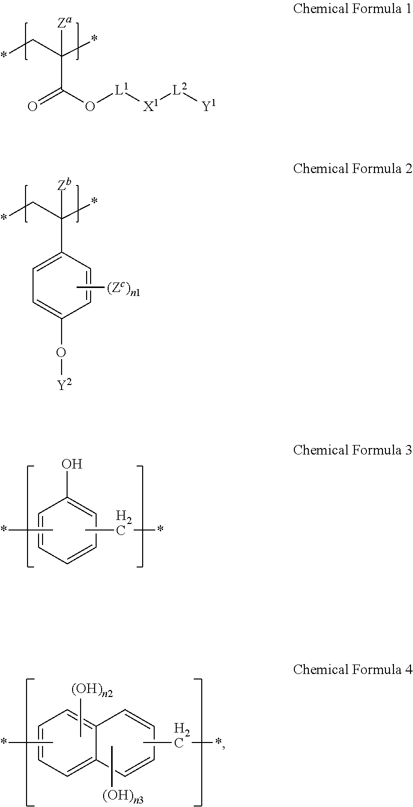
and
wherein, in Chemical Formula 1 and Chemical Formula 2,
L¹ and L² are each independently a single bond, adamantanediol, a substituted or unsubstituted C1 to C10 alkylene group, a substituted or unsubstituted C3 to C10 cycloalkylene group, a substituted or unsubstituted C1 to C20 arylene group, or a combination thereof,
X¹ is a single bond, —O—, —S—, —S(═O)—, —S(═O)₂—, —C(═O)—, —(C═O)O—, —O(C═O)O—, —NR^{a}— (wherein, R^{a} is hydrogen, deuterium, or a C1 to C10 alkyl group), or a combination thereof,
Y¹ and Y² are each independently hydrogen, a hydroxyl group, an adamantyl group, a substituted or unsubstituted C1 to C10 alkyl group, a substituted or unsubstituted C2 to C10 alkenyl group, a substituted or unsubstituted C3 to C20 cycloalkyl group, a substituted or unsubstituted C2 to C20 cycloalkenyl group, a substituted or unsubstituted C6 to C20 aryl group, or a combination thereof,
Z^{a} and Z^{b} are each independently hydrogen or a methyl group,
Z^{c} is a hydroxyl group, a substituted or unsubstituted C1 to C5 alkoxy group, a substituted or unsubstituted C1 to C5 alkyl group, or a combination thereof,
n1 is one of the integers 0 to 4;
wherein, in Chemical Formula 4,
n2 and n3 are each independently an integer from 0 to 3, and n2+n3 is greater than or equal to 1.

5. The method as claimed in claim 1, wherein the boron or metal-containing protective film composition comprises at least one selected from among boron (B), aluminum (Al), titanium (Ti), zirconium (Zr), hafnium (Hf), tin (Sn), antimony (Sb), and tellurium (Te).

6. The method as claimed in claim 1, wherein the boron or metal-containing protective film composition comprises a compound represented by Chemical Formula 5: 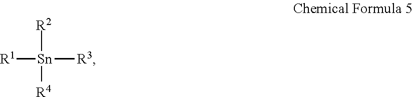
and
wherein, in Chemical Formula 5,
R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one of R² to R⁴ is selected from among alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

7. The method as claimed in claim 6, wherein at least one of R² to R⁴ is selected from among alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

8. The method as claimed in claim 7, wherein R¹ is selected from among a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and a substituted or unsubstituted C7 to C20 arylalkyl group,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

9. The method as claimed in claim 1, wherein the boron or metal-containing protective film composition comprises at least one of a compound represented by Chemical Formula 6 and a compound represented by Chemical Formula 7:
R⁵_{z}SnO_{(2-(z/2)-(x/2))}(OH)ₓ, Chemical Formula 6
wherein, in Chemical Formula 6,
R⁵ is a C1 to C31 hydrocarbyl group, 0<z≤2, and 0<(z+x)≤4;
R⁶ₐSn_{b}X_{c}Y_{d}, Chemical Formula 7
wherein, in Chemical Formula 7,
R⁶ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, ethylene oxide group, propylene oxide group, or a combination thereof, X is sulfur (S), selenium (Se), or tellurium (Te),
Y is —OR^{m} or —OC(═O)Rⁿ, and
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

10. The method as claimed in claim 1, wherein the boron or metal-containing protective film composition comprises a compound represented by Chemical Formula 8 or Chemical Formula 9, or a polymer thereof: 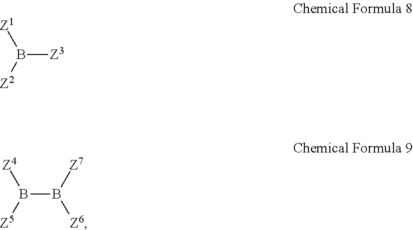
and
wherein, in Chemical Formula 8 and Chemical Formula 9,
Z¹ to Z⁷ are each independently hydrogen, deuterium, a hydroxyl group, a halogen, a nitro group, a cyano group, —NY^{a}Y^{b} (wherein, Y^{a} and Y^{b} are each independently hydrogen, deuterium, a substituted or unsubstituted C1 to C10 alkyl group, a substituted or unsubstituted C6 to C20 aryl group, or a combination thereof), —OY^{c} (wherein, Y^{c} is a halogen, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C6 to C20 aryl group, or a combination thereof.), a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C3 to C20 heterocycloalkyl group, a substituted or unsubstituted C6 to C20 aryl group, a substituted or unsubstituted C3 to C20 heteroaryl group, or a combination thereof, provided that two of Z¹ to Z³ groups and two of Z⁴ to Z⁷ groups are optionally linked to each other to form a ring.

11. The method as claimed in claim 1, wherein the boron or metal-containing protective film composition comprises Al(OR^{p})₃, Ti(OR^{q})₄, Zr(OR^{r})₄, Hf(OR^{s})₄, Sb(OR^{t})₃, Te(OR^{u})₄, TeR^{v}₄, or a combination thereof, wherein RP to Ru are each independently —C(═O)R^{x} (wherein, R^{x} is a substituted or unsubstituted C1 to C10 alkyl group), a substituted or unsubstituted C1 to C10 alkyl group, or a substituted or unsubstituted C6 to C20 aryl group, or a combination thereof, and R^{v} is a halogen.

12. The method as claimed in claim 1, wherein the boron or metal-containing protective film composition comprises a compound represented by one or more of Chemical Formula 11 to Chemical Formula 26:

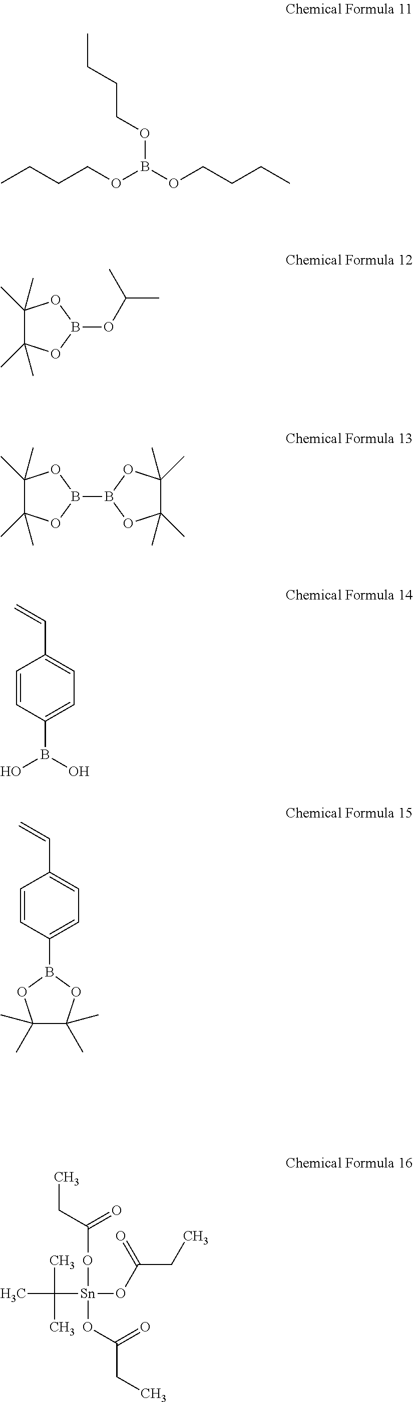

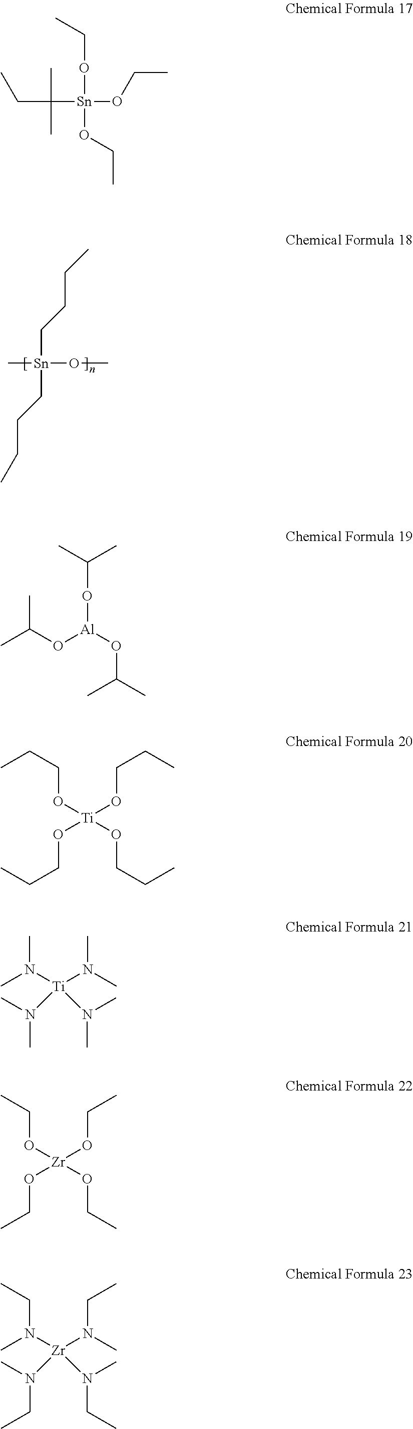

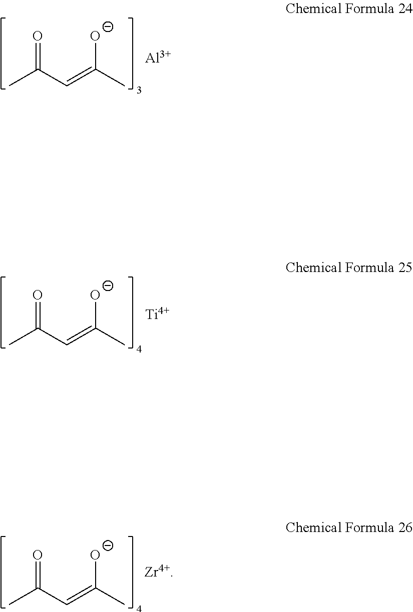

13. The method as claimed in claim 1, wherein a developer for developing the organic photoresist layer is at least one selected from among tetramethylammonium hydroxide, tetraethylammonium hydroxide, tetrapropylammonium hydroxide, tetrabutylammonium hydroxide, and n-butyl acetate.

14. The method as claimed in claim 1, wherein a solution for developing the overcoated photoresist layer is at least one selected from among methylethylketone, acetone, cyclohexanone, 2-heptanone, 4-methyl-2-propanol, 1-butanol, isopropanol, 1-propanol, methanol, propylene glycol monomethyl ether acetate, ethyl acetate, ethyl lactate, n-butyl acetate, butyrolactone, dibutyl ether, diisopentyl ether, propylene glycol monomethyl ether, benzene, xylene, and toluene.
